(19) United States
(12) Patent Application Publication
(10) Pub. No.: US 2022/0384682 A1
(43) Pub. Date: Dec. 1, 2022

(54) FORMATION OF MICROLED MESA STRUCTURES WITH ATOMIC LAYER DEPOSITION PASSIVATED SIDEWALLS, A SELF-ALIGNED DIELECTRIC VIA TO THE TOP ELECTRICAL CONTACT, AND A PLASMA-DAMAGE-FREE TOP CONTACT

(71) Applicant: The Regents of the University of California, Oakland, CA (US)

(72) Inventors: Jordan M. Smith, Goleta, CA (US); Steven P. DenBaars, Goleta, CA (US)

(73) Assignee: The Regents of the University of California, Oakland, CA (US)

(21) Appl. No.: 17/772,715

(22) PCT Filed: Oct. 28, 2020
(86) PCT No.: PCT/US20/57695

§ 371 Date: Apr. 28, 2022

Related U.S. Application Data
(60) Provisional application No. 62/926,950, filed on Oct. 28, 2019.

(51) Int. Cl. H01L 33/32; H01L 27/15; H01L 33/62; H01L 33/00

(52) U.S. Cl. CPC H01L 33/32; H01L 27/156; H01L 33/62; H01L 33/005

(57) ABSTRACT

A micro light emitting diode including a mesa comprising an epitaxial structure and having a top surface with an area less than 10 micrometers by 10 micrometers, less than 1 micrometer by 1 micrometer, or less than 0.5 micrometers by 0.5 micrometers; a dielectric on the top surface; and a via hole in the dielectric that is centered or self aligned on the top surface, e.g., perfectly centered or centered within 0.5% of the center of the top surface. In one or more examples, the micro light emitting diode is plasma damage free. Metallization in the via hole is used to electrically contact the micro light emitting diode.

### CROSS REFERENCE TO RELATED APPLICATIONS

This application claims the benefit under 35 U.S.C 119(e) of co-pending and commonly-assigned U.S. Provisional Patent Application No. 62/926,950, filed Oct. 28, 2019, by Jordan M. Smith and Steven P. DenBaars, entitled “FORMATION OF MICROLED MESA STRUCTURES WITH ATOMIC LAYER DEPOSITION PASSIVATED SIDEWALLS, A SELF-ALIGNED DIELECTRIC VIA TO THE TOP ELECTRICAL CONTACT, AND A PLASMA-DAMAGE-FREE TOP CONTACT” Attorney's Docket No. 30794.750-US-P1 (2020-080-1), which application is incorporated by reference herein.

### BACKGROUND OF THE INVENTION

### 1. Field of the Invention

The present invention relates to optoelectronic devices and methods of making the same.

### 2. Description of the Related Art

(Note: This application references a number of different references as indicated throughout the specification by one or more reference numbers in brackets [x]. A list of these different publications ordered according to these reference numbers can be found below in the section entitled “References.” Each of these publications is incorporated by reference herein.

Micro light emitting diode (microLED) technology has potential uses in a variety of future display and communications applications. As a result, those skilled in the art continue with research and development efforts in the field of micro LEDs in order to improve device performance. The present disclosure satisfies this need.

### SUMMARY OF THE INVENTION

The invention disclosed is a microLED mesa structure, as well as the process leading to its formation. Example applications of the microLED mesa include use in communications applications as well as use as pixels in displays. It is highly desirable to have a microLED mesa that has the following features:

1) Small lateral dimension on the order of one micron (smaller mesas=smaller displays and less wasted material).

2) Perfectly aligned/centered dielectric via (essentially a hole in the dielectric layer to allow the p-side of the mesa structure to be electrically contacted).

3) No ion damage to the p-side material and/or contact due to dry etching (liftoff or wet etching is preferred).

4) Nonradiative recombination at the sidewalls of the microLEDs suppressed by various treatments such as wet chemical treatments, high temperature annealing, and atomic layer deposition (ALD) to passivate dangling bonds. All these increase efficiency of microLEDs.

The present disclosure reports on the first process that can incorporate all four features mentioned above in a commercially viable manner (i.e., using methods that are standardized throughout the semiconductor manufacturing industry).

One or more examples of a novel process described herein achieve all four features described above. In one or more examples, the relative difficulty/complexity (in terms of manufacturing time and cost) of the novel process(es) described herein is also comparable to conventional methods used to fabricate LEDs/microLEDs.

Example methods and devices disclosed herein include, but are not limited to, the following.

1. A method of making a light emitting device, comprising:

(a) obtaining an epitaxial structure for the device, the epitaxial structure including an n-type layer, a p-type layer, and an active region between the n-type layer and the p-type layer;

(b) depositing a first hardmask layer comprising a first material on the epitaxial structure:

(c) depositing a second hardmask layer comprising a second material on the first hardmask layer, wherein the first hardmask layer and the second hardmask layer are at least partially resistant to a wet chemical solution used in step (e);

(d) patterning the first hardmask layer, the second hardmask layer, and the epitaxial structure using lithography so as to form a mesa comprising the epitaxial structure, wherein the patterning includes selectively etching the first hardmask layer over the second hardmask layer so as to form an undercut structure comprising the second hardmask layer extending laterally beyond the edges of the underlying patterned first hardmask layer;
(e) performing one or more sidewall treatments so as to remove impurities, defects and passivate dangling bonds from sidewalls of the mesa, wherein the sidewall treatments include a dip of the sidewalls in the wet chemical solution;
(f) depositing an ALD layer on the sidewalls using atomic layer deposition (ALD);
(g) depositing a dielectric layer on the ALD layer using a directional deposition method so that a discontinuity in the dielectric layer is formed, the discontinuity exposing the ALD layer surrounding the first hardmask layer;
(h) removing the ALD layer surrounding the first hardmask layer and exposed by the discontinuity, using an etching technique; and
(i) etching the first hardmask layer, thereby removing the first hardmask layer and all of the layers above the first hardmask layer, leaving a via hole in the dielectric layer on top of the mesa having a location and a first area defined by the position and second surface area of patterned hardmask layer prior to removal of patterned first hardmask layer, so that the via hole exposes a top surface of the epitaxial structure in the mesa.

2. The method of example 1, wherein the first material and the second material comprise one or more dielectrics.

3. The method of examples 1 or 2, wherein the device is a micro light emitting diode.

4. The method of example 3, wherein the micro led includes the mesa having a surface area of 10 microns by 10 microns or less.

5. The method of any of the examples 1-4, wherein the etching removing the hardmasks and the ALD material comprises vapor or wet etching.

6. The method of any of the examples 1-5, wherein the ALD layer comprises a dielectric and the dielectric layer on the ALD layer is thicker than the ALD layer.

7. The method of any of the examples 1-6, wherein the dielectric layer deposited on the ALD layer is resistant to the etching used to remove the first hardmask layer.

8. The method of any of the examples 1-7, wherein removing all of the layers above the first hardmask layer includes removing the second hardmask layer and a photoresist layer used for the patterning of the mesa.

9. The method of any of the examples 1-8, further comprising depositing metallization in the via hole so as to form an ohmic contact to the top surface of the epitaxial structure comprising an n-type layer or a p-type layer.

10. The method of any of the examples 1-9, wherein the epitaxial structure comprises III-nitride.

11. A micro light emitting diode, comprising:

a mesa comprising an epitaxial structure and having at least one of:
a top surface with an area of 10 micrometers squared or less, or
at least one of a diameter, a largest width, or a largest dimension of 10 micrometers or less;

a dielectric on the top surface; and a hole in the dielectric that is centered or self aligned on the top surface.

12. The micro light emitting diode of example 11, comprising the area being:

1 micron squared or less, or

0.5 microns squared or less.

13. The micro light emitting diode of example 11, comprising at least one of the diameter, the largest width, or the largest dimension being:

5 microns or less,

1 micron or less, or

0.5 microns or less.

14. The micro LED of any of the examples 11-13, wherein the micro LED comprises III-nitride.

15. The LED of example 14, further comprising metallization in the hole forming an ohmic contact with the epitaxial structure.

16. The micro LED of any of the examples 11-15, wherein:

the epitaxial structure comprises an n-type layer, a p-type layer, and an active region between the n-type layer and the p-type layer,

a first contact in the hole forms an ohmic contact with the n-type layer or the p-type layer, and

the active region emits electromagnetic radiation in response an electric field across the n-type layer and the p-type layer, the electric field formed by a potential difference between the first contact and a second contact to the micro light emitting diode.

17. The LED of any of the examples 11-16, wherein the hole has a diameter of 2 microns or less.

18. The LED of examples 11-17, wherein the hole has a first center within 0.5% of a second center of the top surface.

19. The micro light emitting diode of any of the examples 11-18, wherein the light emitting diode is plasma damage free.

20. An array of the micro light emitting diodes of any of the examples 11-19.

21. A display comprising the array of example 20, wherein the array comprises pixels each comprising at least one of the micro light emitting diodes.

22. The array of micro light emitting diodes of examples 20 or 21 manufactured using the method of any of the examples 1-10.

23. The device of any of the examples 11-22, wherein:

each of the micro light emitting diodes emit electromagnetic radiation for a current density of at least 100 amps per centimeter square in the epitaxial structure comprising in response to a bias of at least 2.5 volts applied across the epitaxial structure between a first contact to the epitaxial structure in the hole and a second contact to the epitaxial structure, and

the first contact is electrically connected to an n-type layer in the epitaxial structure and the second contact is electrically connected to a p-type layer in the epitaxial layer, or the first contact is electrically connected to the p-type layer and the second contact is electrically connected to a n-type layer.

24. The device of any of the examples 11-23, wherein the first contact or the second contact are connected to the p-type layer via an n-type region in a tunnel junction.

25. The device of any of the examples 11-24, wherein at least one of the first contact and the second contact comprise a metal layer.

26. A device comprising the micro light emitting diode of any of the examples 11-25 manufactured using the method of examples 1-10.

27. The device of any of the examples 11-26, wherein the epitaxial structure comprises or consists essentially of a semiconductor including comprising a III-nitride material or a III-V material.

28. The device of any of the examples 11-27, wherein the mesa includes sidewalls and at least one of a dielectric or passivation on the sidewalls.

### BRIEF DESCRIPTION OF THE DRAWINGS

Referring now to the drawings in which like reference numbers represent corresponding parts throughout:

FIG. 1 (left): Typical microLED manufacturing process chain. https://semiengineering.com/microleds-the-next-revolution-in-displays/. Embodiments of the invention disclosed herein pertain to the “singulation” step.

FIG. 2. A microLED mesa structure and its layers.

FIG. 3. Process and final device structure according to embodiments of the present invention, showing step I (LED structure), step II (deposition of contact layer and hardmask layers), step Ill (use of lithography and etching to define mesa structure), Step IV (selectively etching hardmask 1 via wet or dry etching to create undercut profile, Step V (chemical sidewall treatment followed by ALD dielectric deposition for sidewall passivation, Step VI (depositing dielectric for electrical isolation), Step VII (selectively removing ALD dielectric contacting hardmask 1 using wet etching), and Step VIII (etch away hardmask 1 to create a via/hole through the dielectric materials.

FIG. 4. Example processing methods for manufacturing microLED mesas a) lift-off process b) dry etch process c) wet etch process.

FIG. 5. Process with specific materials and chemicals as an example of the present invention, showing step I (LED structure), step II (deposition of ohmic ITO layer and hardmasks), step III (use of lithography and etching to define mesa structure), Step IV (selectively etching silicon dioxide (SiO2) hardmask using buffered hydrofluoric acid (HF) solution, Step V (KOH (potassium hydroxide) sidewall chemical treatment followed by deposition of 10 nm thickness of aluminum oxide (Al₂O₃) using ALD, Step VI (sputtering a thick aluminum oxide dielectric layer, also shown in FIG. 7A), Step VII (Remove ALD dielectric material protecting the SiO2 hardmask by using dilute TMAH as an etchant), and Step VIII (Etch away SiO2 using vapor HF to release undercut structure and create via).

FIG. 6. Schematic and actual Scanning Electron Microscope (SEM) image of the structure formed using the process depicted in FIG. 5 step IV (Selectively etch hardmask 1 via wet or dry etching to create an undercut profile), according to one or more embodiments.

FIG. 7A. Schematic and actual SEM image of the structure formed using the process depicted in FIG. 5 step VI (Deposit dielectric for electrical isolation), according to one or more embodiments.

FIG. 7B. Schematic and SEM image of the structure formed using the process depicted in FIG. 5 step VIII (etch away hardmask 1 to create a via/hole through the dielectric materials), according to one or more embodiments of the present invention.

FIG. 7C. Schematic showing position of the center of the hole and top surface of mesa.

FIG. 8. Image of 1 micron diameter microLED and electroluminescence from the microLED, wherein the microLED is fabricated using the process of FIG. 3 and FIG. 5 disclosed herein.

FIG. 9A. Current-Voltage data of microLEDs of various sizes fabricated using the processes of FIG. 3 and FIG. 5 described herein.

FIG. 9B. Table 1.

FIG. 10. (a) Blanket deposition of 30 nm ITO, 300 nm SiO2, and 200 nm Si3N4 on top of LED epitaxial structure. (b) Dry etch through various layers to define mesa structure. (c) Selectively undercut SiO2 layer using buffered HF solution. (d) Sputter deposition 250 nm Al2O3 passivation material. (e) Liftoff by removing SiO2 layer using vapor HF. (f) Dry etch Al2O3 to expose n-GaN and deposit reflective 600/100/600 nm Al/Ni/Au common contacts/probe-pads via e-beam evaporation and lift-off.

FIG. 11. SEM micrograph of a 1 μm diameter InGaN microLED mesa with Al2O3 dielectric passivation and aperture showing exposed ITO, corresponding to FIG. 10(e).

FIG. 12. Comparison of current-voltage characteristics of 1 μm and 10 μm diameter devices for blue and green wavelengths.

FIG. 13. EQE vs logarithmic current density for devices 1-30 μm in size for (a) blue and (b) green wavelengths. Results for devices with highest measured peak EQE are shown (corresponding to the upper ranges in FIG. 14).

FIG. 14. Peak EQE as a function of mesa diameter for blue and green devices. Upper ranges correspond to the peaks in FIG. 13.

FIG. 15. Current density at the peak EQE, Jmax, as a function of mesa diameter for blue and green devices.

FIG. 16 illustrates additional details and SEM micrographs of the process developed to fabricate microLEDs down to 1 μm, showing (a) Blanket deposition of 30 nm ITO via e-beam evaporation, and DC reactive magnetron sputter deposition of 300 nm SiO2+200 nm SiN on top of c-plane LED MQW structures grown on sapphire, (b) Consecutively dry etch through layers with various etch chemistries to define mesa structures ranging 1-30 μm in diameter, (c) Dip (˜30s) in buffered hydrofluoric acid (BHF) to selectively etch SiO2 layer and create undercut. (d) Deposit 250 nm of Al2O3 using DC reactive magnetron sputtering, (e) lift-off by complete removal of SiO2 layer using vapor HF etching, and (f) Dry etch through Al2O3 layer to expose n-GaN for n-contact formation. Deposit 600/100/600 nm Al/Ni/Au contact pads on top of mesa (p-contact) and on exposed n-GaN (n-contact). All other layers are resistant to vapor HF etching. Etch depth of the epitaxial layers is approximately 1 μm.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

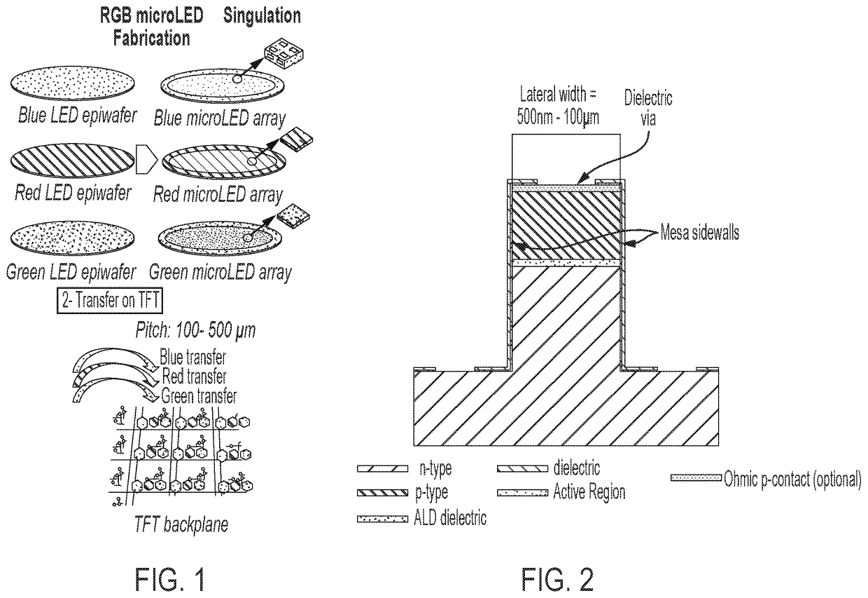

A typical microLED manufacturing chain is shown in FIG. 1. Arrays of microLED mesas such as the one shown in FIG. 2 may be manufactured semiconductor processing methods such as photolithography, deposition and wet/dry etching. Afterwards, these microLED mesas must all be connected to additional circuitry as shown in step 3 of FIG. 1 to form a working device such as a display.

Embodiments of the invention disclosed herein pertain specifically to the second “singulation” step in FIG. 1 which consists of forming arrays of closely spaced microLED “mesas” on the epitaxial wafers grown in step 1 of FIG. 1. The invention is a final “microLED mesa” structure shown in FIG. 2 which has improved efficiency and other properties compared to other microLED mesas, as well as the process used to achieve the final mesa structure shown in FIG. 2. Although embodiments of the present invention pertain to the singulation step in FIG. 1, the material properties of the layers grown in the “epiwafer” in FIG. 1 are crucial for operation of a microLED. In general, the materials used to form the epitaxial structure (FIG. 1 step 1) consist or comprise of Al, Ga. In, and N (III-Nitrides) or Al, Ga, In, As and P (III-Vs) of various concentrations. Typically, one side of the LED is doped “p-type” and the other “n-type” with an active region sandwiched between them as shown in FIG. 2. This sandwich structure is commonly referred to as a PIN junction and forms the basis for all modem LEDs. Typical operation of microLEDs consists of, or comprises, injecting holes from the “p-type” material and electrons from the “n-type” material of a mesa by electrically contacting both layers through the p-side (e.g., top) and the n-side (e.g., bottom) with metal contacts through the dielectric vias (holes in the green layer—a via is a common term used in the semiconductor industry to describe a hole through a particular layer which allows for electrical contact to be made to the underlying layer).

The dielectric layer is necessary to isolate the p and n contacts so that the device does not short. When forward bias is applied across the p-type—intrinsic region-n-type (PIN) junction, electrons and holes are forced to meet in the active region of the device shown in FIG. 2 and recombine to emit light. In some cases, the PIN structure may be replaced by a more complicated structure, such as a tunnel junction LED; however, changing the epitaxial structure does not change the underlying principles of LED operation, and all the processes described in the present disclosure would still be applicable. Embodiments of the present invention can be applied to PIN structures consisting of or comprising either III-Nitride or III-V materials and has been fully demonstrated on III-Nitride materials.

MicroLED technology is differentiated from standard LED technology by the lateral dimensions of the mesa structures (see FIG. 2). Although there is no strict definition of the size-regime encompassed by microLED technology, mesa structures with lateral dimensions between 0.5 μm-100 μm are typically considered to be microLEDs, like that shown in FIG. 2. MicroLED mesas on the smaller side of this range (i.e. <10 μm) are desirable for most commercial applications; this is due to the fact that smaller dimensions allow more microLED mesas to be fabricated on the same wafer, which will result in reduced material costs (more microLEDs per unit area.) Considering this, the findings and embodiments of the present invention disclosed herein may be used for (and will be most beneficial/necessary) for fabrication of the smallest mesa structures, although the invention can work for LED mesas of any size greater than 0.5 μm. One key commercial advantage of the present invention is that it can, in some examples, be used for the production of microLED mesas in the most desirable size range for most commercial applications (0.5 μm-10 μm).

The most promising route for commercialization of microLED technology requires fabricating microLEDs using conventional “top-down” semiconductor fabrication methods (e.g. photolithography, deposition and wet/dry etching). These methods have been largely standardized by the semiconductor (silicon) industry and thus provide the most obvious cost-efficient route. One key commercial advantage of embodiments of the present invention is that it can be accomplished/created using typical/established semiconductor fabrication methods which reduce fabrication costs. Another key commercial advantage of embodiments of the present invention is that it reduces the number of photolithography steps required to create a typical mesa structure (compared to conventional LED manufacturing processes like the one shown in FIG. 1) thereby reducing manufacturing cost and complexity.

As the lateral size of the microLED mesa is reduced, a number of challenges arise which inhibit/prevent the use of conventional top-down fabrication approaches used to form larger LEDs. Below is a summary of the issues that arise when fabricating the smallest microLEDs, as well as how the present invention disclosed solves those problems:

Layer-to-Layer Misalignment

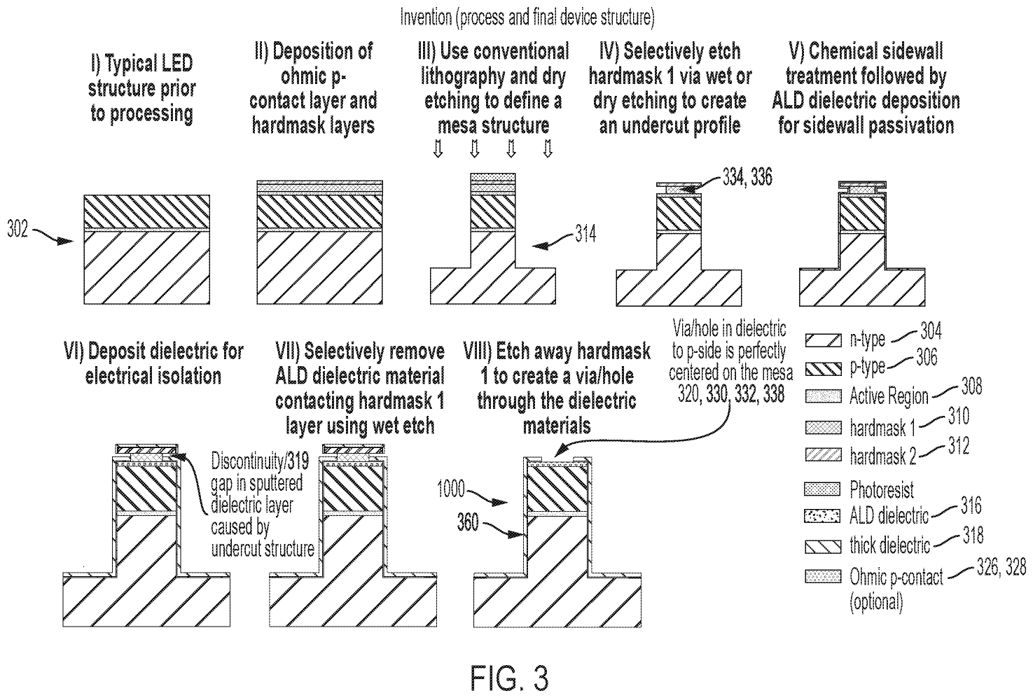

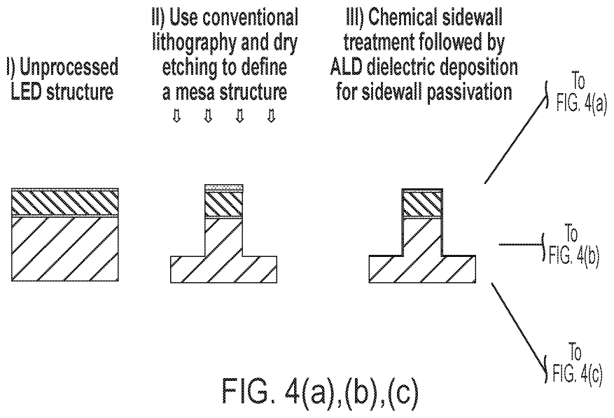

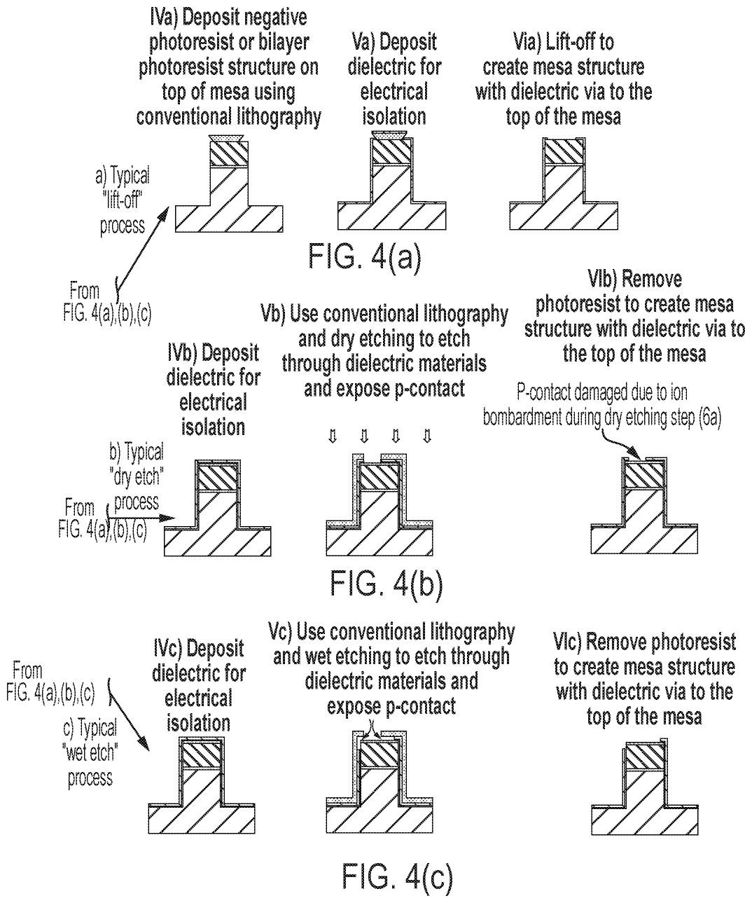

When photolithography is used to create various structures in semiconductor devices, it is necessary to align certain layers on top of one another. In practice, these layers arc never aligned perfectly (there is some nonzero lateral misalignment). When the sizes of mesas are reduced, the negative effects of misalignment are exacerbated as the lateral size of the mesa approaches the value of the misalignment. One particular step in typical LED/microLED manufacturing processes that is sensitive to misalignment, is the creation of the dielectric via on top of the mesa structure. If the via is severely misaligned, such that the via is located over the edge of the mesa instead of on top of the mesa, it will result in a shorted/dead/bad device. Even if the dielectric via is only slightly misaligned (like that shown in FIG. 4, step VIa-VIc) this still causes unwanted variations in the performance of devices with different degrees of misalignment. One key commercial advantage of embodiments of the present invention is that it can, in some examples, create a dielectric via on top of the p-side of the mesa structure that is perfectly centered/aligned like that shown in FIG. 3 step VIII (in contrast to that shown FIG. 4, steps VIa-VIc). This ensures there will no, or reduced, device shorting or variations in the performance of the microLED mesas due to misalignment. A common term for these types of processes that have no (or reduced) misalignment are “self-aligned processes”.

Nonradiative Sidewall Recombination

It has been observed by researchers that the efficiency of microLEDs decreases as the lateral dimensions decrease. This has been attributed to nonradiative recombination of carriers at the sidewalls of the mesa structures due to a large number of defects, impurities, and dangling bonds which create defect states/traps in the bandgap of the materials. As lateral sizes are reduced, the ratio of sidewall surface area to total volume of the microLED active region is increased, leading to a reduction in efficiency. It has been shown by the inventors of the present invention that wet chemical sidewall treatments, high temperature annealing, and atomic layer deposition (ALD) passivation can all help remove these defect states through various means (the underlying physics of which are still up for debate). Thus, it is important for a microLED manufacturing process to be able to incorporate one or all of these treatments to improve the efficiency of microLEDs, especially at small sizes. Unfortunately, many of these techniques are not compatible with typical microLED manufacturing methods: in particular, photoresist is damaged/etched/destroyed/incompatible with all three techniques described above which restricts many typical processes. One key commercial advantage of embodiments of the present invention is that it permits, in some examples, all the sidewall treatments known to reduce nonradiative sidewall recombination (including wet chemical treatments, annealing and ALD passivation). This will lead to improved efficiency/performance of microLED devices, especially at the smallest sizes.

Ion/Plasma Damage to p-Contact

The dielectric via (hole in the dielectric layer on top of the mesa shown in all Fig.s) is typically created by a dry etching process (the typical process is shown in FIG. 3b). Lithography is used to pattern a hole in the photoresist above the mesa; then, this hole is transferred into the dielectric layer below using typical plasma-based dry etching process, e.g. reactive ion etching (RIE) or inductively coupled plasma (ICP) etching. However, during this process the ion bombardment used to etch the dielectric layer can also damage the underlying p-contact material. The damage caused to the p-contact layer can degrade the electrical properties of the contact which can result in less efficient or non-working microLEDs. The conventional LED “lift-off” process shown in FIG. 3a or the “wet etch” process in FIG. 3c can avoid damaging the p-contact, but have other issues (discussed elsewhere) that make them extremely difficult or impossible for use in manufacturing the smallest microLEDs (0.5 μm-10 μm). One key commercial advantage of embodiments of the present invention is that it creates a dielectric via on top of microLED mesas without causing damage to the underlying contact/material due to ion bombardment. Another key aspect is that a process according to embodiments described herein works well for even the smallest microLEDs, and is largely independent of the size of the mesa. This creates a desirable combination of high efficiency and small mesa sizes.

Example Process Steps

Below is a detailed description of an example process according to the present invention and a process used to make a microLED mesa structure (FIG. 3). Several other common processes used for manufacturing microLEDs and conventional LEDs are also described (FIG. 4) and compared in order to highlight the key commercial advantages achieved using embodiments of the present invention as compared to conventional processes.

FIG. 3 illustrates a method of making a device, according to one or more examples, comprising the following steps.

Step 3I): Typical LED epitaxial structure before processing. The GaN materials shown can be replaced by InGaAsP materials.

Step 3II): Deposition of ohmic p-contact (typically, but not limited to, ITO in GaN) and dielectric hardmask layers 1 and 2. The ohmic p-contact layer is optional and can alternatively be deposited after the final step shown in all the process FIGS.

In one or more examples, hardmask layers 1 and 2 are dielectric materials and can be deposited using multiple methods. The materials in layer 1 and 2 are specifically chosen based on their etch characteristics (i.e., etch rate) in the chemicals used in the proceeding or following steps.

Step 3III): A mesa structure is defined by patterning a (e.g., photoresist) hardmask, e.g., using conventional lithography. The shape and lateral width of the (e.g., photoresist) hardmask will determine the final shape and width of the microLED mesa. The smallest lateral dimension possible is, in some examples, limited by the wavelength of light used in the lithography system and is, for example, typically around 0.5 μm. The (e.g., photoresist) hardmask pattern is then transferred to the underlying layer through dry etching. All the layers above the n-GaN layer must be etched, and the n-GaN may or may not be etched all the way down to the substrate.

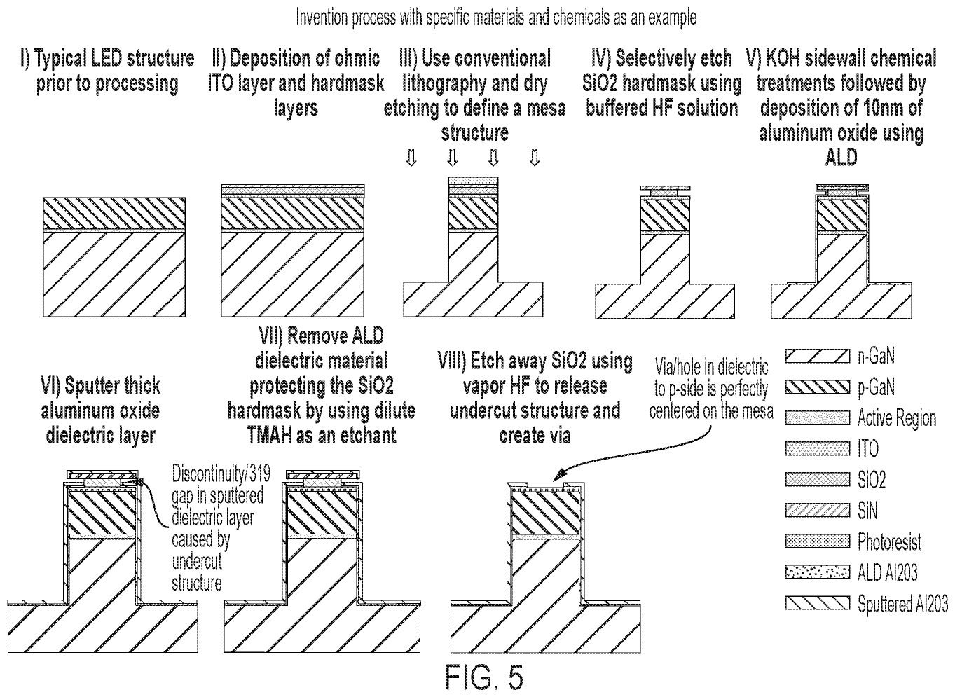

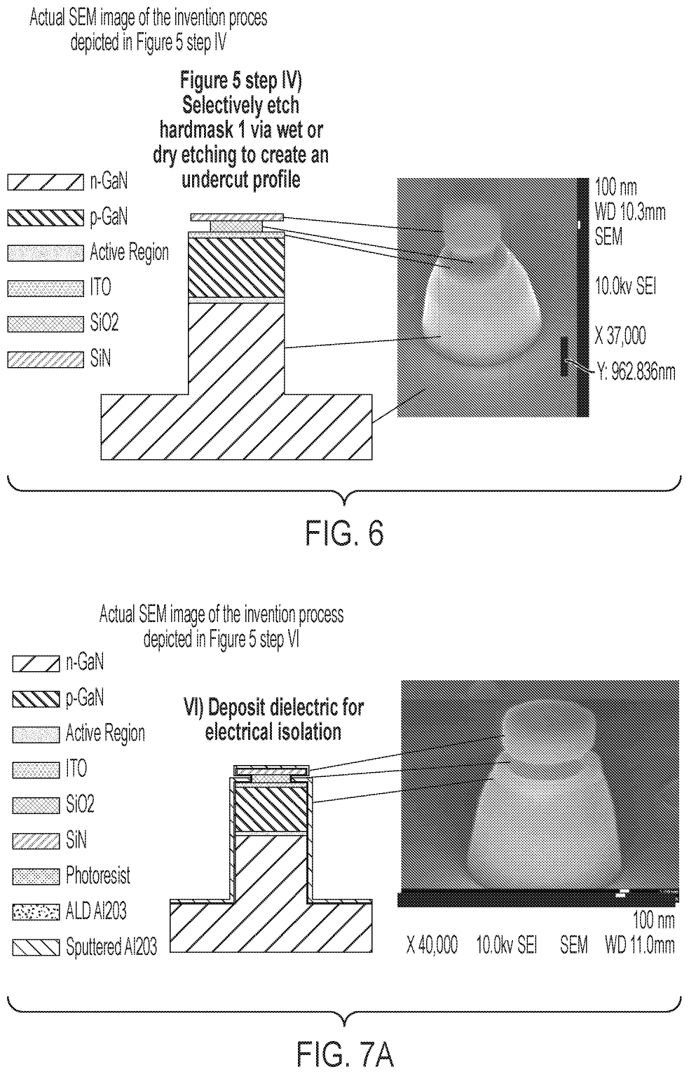

Step 3IV): Hardmask 1 is selectively etched over hardmask 2 to create the undercut structure or profile shown in FIG. 3IV that rests on top of the mesa (i.e., the hardmask 1 layer and hardmask 2 layer where the hardmask 1 layer is smaller in width than the hardmask 2 layer so as to create the observed overhang or undercut structure). A real image of this structure is shown in FIG. 5.

This undercut structure is one of the most crucial components of embodiments of the present invention. Undercut structures are typically used in semiconductor processing for “lift-off” techniques. In a lift-off technique, a thin film (such as a metal or dielectric) is deposited over the entire surface, including the undercut structure. Due to the undercut structure, there is a discontinuity in the deposited film (see FIG. 3VI and FIG. 4Va). This allows the underlying layer to be etched away by chemical means, leaving a hole/via (area with no deposited material) where the undercut structure originally was located. A benefit of using a lift-off process is that does not require etching through materials, since this often results in damaging the underlying layers (such as the p-side material in LEDs) due to ion bombardment. Conventional lift-off processes use an undercut structure composed of photoresist material which is patterned using conventional lithography. However, there are a number of drawbacks to using photoresist lift-off processes when forming small microLED mesas: 1) lift-off using photoresist becomes quite difficult and unrepeatable at small sizes ˜1 micron (the same size of the microLEDs) due to poor resolution and structural instability 2) photoresist is not compatible with many chemical sidewall treatments (especially bases such as KOH) or high temperature treatments including ALD and 3) there is always some misalignment, as is the case with all lithography processes. The undercut structure formed in FIG. 3IV solves all three issues faced by lift-off processes using conventional photolithography. Since the hardmask 1 and hardmask 2 layers are not made of photoresist, they can be chosen so that they are resistant to whichever chemical treatment is used, for example KOH. Hardmask 1 and hardmask 2 can be dielectric materials, ceramics, or metal materials, all of which should withstand high temperatures (˜300° C.) used in ALD (in contrast to photoresist). Finally, since the hardmask lift-off structure is self-aligned (in that it was formed simultaneously on top of the mesa as the mesa was etched) there are no misalignment errors.

Step 3V: Various sidewall treatments are applied during this step, with the purpose of removing impurities, defects and satisfying dangling bonds which results in increased efficiency of microLEDs. Sidewall treatments include, for example, dips in wet chemical solutions which are thought to etch away damaged material on the sidewall, as well as passivate dangling bonds. The exact chemical used depends on the epitaxial material (e.g. III-Nitride or III-V). Hardmask 1 and 2 and the ohmic p contact are all chosen to be resistant to the wet chemical used so they remain after the wet chemical treatment. After wet chemical treatments, dangling bonds on the sidewall are passivated, e.g., using ALD. ALD deposition is better suited for satisfying dangling bonds compared to other dielectric deposition methods (such as sputtering, electron beam evaporation and chemical vapor deposition). The chosen ALD material is dependent on the chemical compatibilities of the other layers and etchants used in the process.

Step VI: A dielectric layer (thicker than the ALD dielectric) is deposited using a directional deposition method (as opposed to a conformal deposition method) such as sputtering or electron beam evaporation. Due to the undercut feature created in step IV, a discontinuity in the deposited dielectric is formed as shown in step VI. This discontinuity exposes the ALD dielectric material surrounding hardmask layer 1, which allows for the removal of the hardmask in the proceeding or following steps. In some cases, the thicker dielectric layer may be the same material as the ALD dielectric layer. In some cases, multiple dielectrics may be layered to create the thick dielectric layer. The dielectric layer is chosen to have chemical etch resistance to the chemical used to etch hardmask 1 in the final step VIII. In various examples, the dielectric is deposited for electrical isolation.

Step VII: The thin ALD material surrounding/protecting hardmask 1 is etched away, e.g., using vapor or wet etching.

Step VIII: Hardmask 1 is etched away, e.g., by either vapor etching or wet chemical etching. Removing hardmask 1 also removes all of the layers above it, resulting in the creation of a dielectric via (hole in the dielectric material) on top of the mesa structure. This dielectric via differs from the dielectric vias in FIG. 4 since it is perfectly centered on top the mesa (self-aligned). In some cases, hardmask 1 is etched using the same chemical used to create the undercut in IV, while in other cases, a different chemical or method may be used. The dielectric layer deposited in step VI is chosen to be resistant to the chemical used to etch hardmask 1 in this final step.

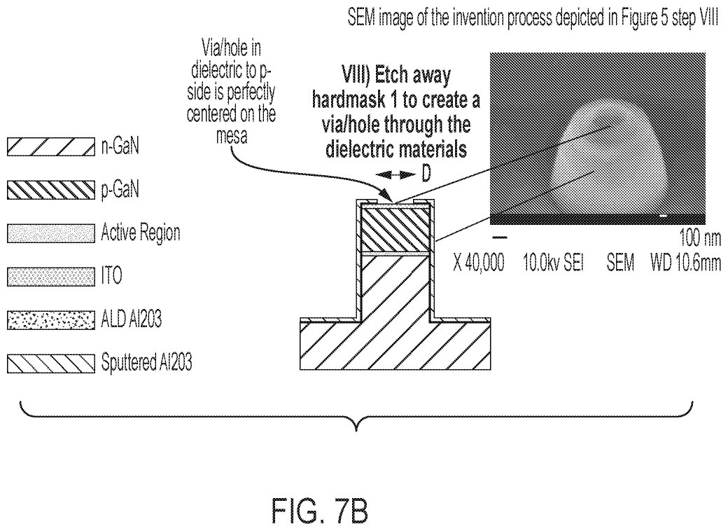

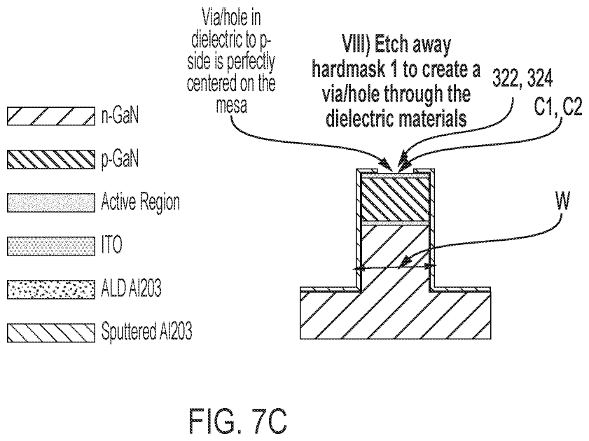

FIG. 5 depicts the same process flow shown in FIG. 3, except with specific examples of materials used. In addition, several actual photos of the various steps in the process are shown. The microLED mesas shown in the SEM photo are fabricated from III-Nitride materials. The mesa depicted has a lateral size on the order of 1 μm. FIG. 6 shows an SEM image of the structure formed in FIG. 5 step IV. FIG. 7A shows an SEM image of the structure formed in FIG. 5 step VI, and FIG. 7B shows an SEM image of the structure formed in FIG. 5 step VIII.

FIG. 4 shows three common processes that can be used for making microLEDs, dubbed a) “lift-off” b) “dry etch” and c) “wet etch” processes. These Figs are intended to show how the vast majority of LED and microLED mesas are fabricated, although it is not an exhaustive overview. The purpose of FIG. 4 is to highlight how it is not possible to achieve the final structure shown in FIG. 3VIII with any other processes. However, all of these processes have some drawbacks, especially for fabricating extremely small microLEDs having widths of ˜1 μm.

FIG. 6. Actual Scanning Electron Microscope (SEM) image of the structure formed using the process depicted in FIG. 5 step IV, according to one or more embodiments.

FIG. 7A. Actual Scanning Electron Microscope (SEM) image of the structure formed in FIG. 5 step VI, and FIG. 7B shows the SEM image of the structure formed using the process depicted in FIG. 5 step VIII, according to one or more embodiments of the present invention.

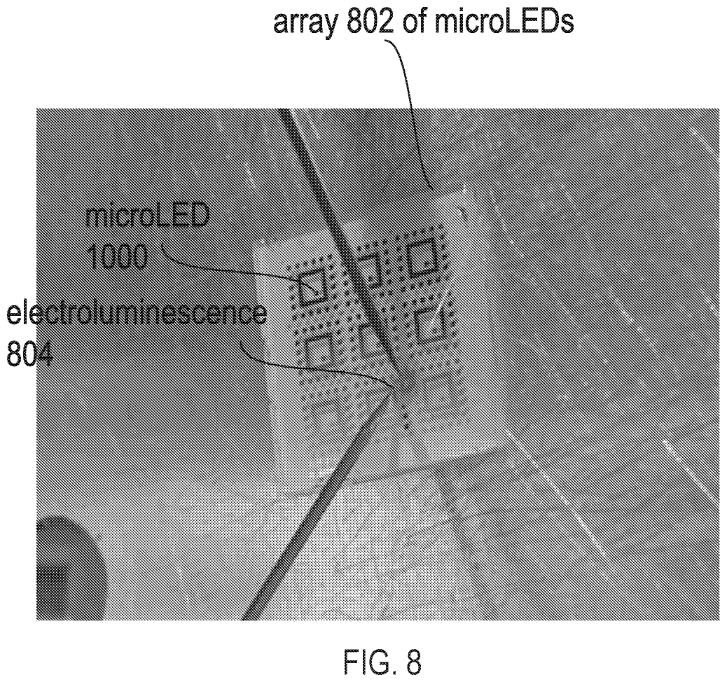

FIG. 8. Image of 1 micron microLED electroluminescence fabricated using the process disclosed herein.

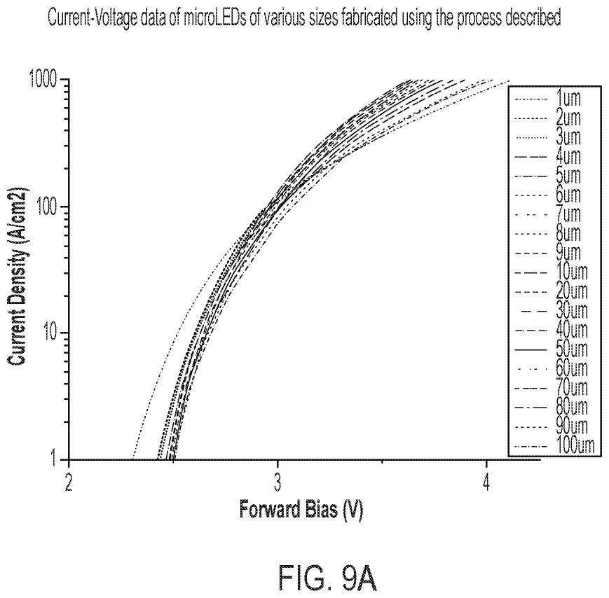

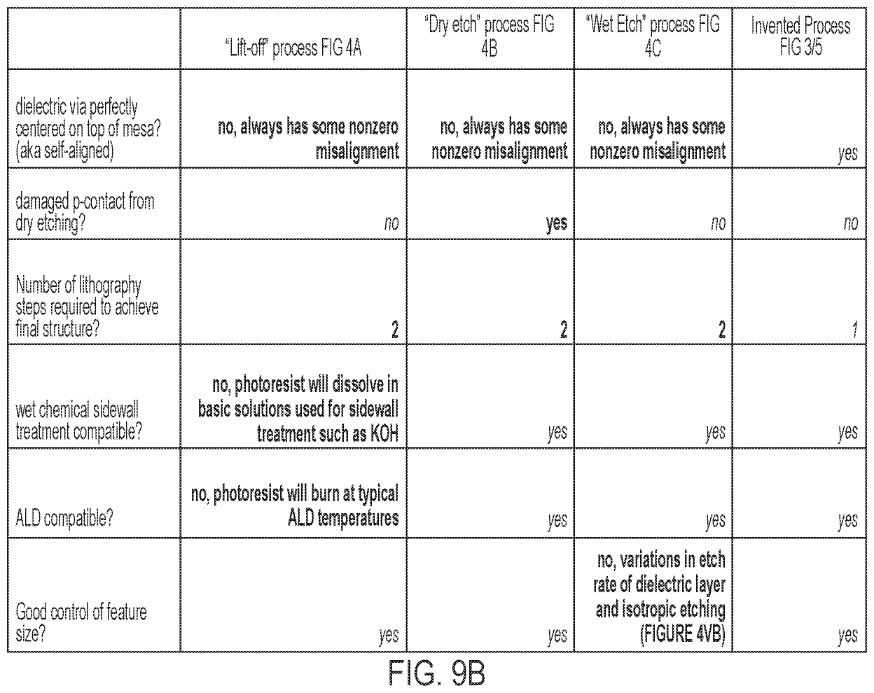

FIG. 9. Current-Voltage data of microLEDs of various sizes fabricated using the process described herein.

Table 1

Table 1 in FIG. 9B compares the process according to embodiments described herein to the other three common process types mentioned.

Embodiments of the present invention combine the best aspects of other processes in order to achieve extremely small microLED mesas (e.g., ˜1 micron as shown in the SEM photos of FIG. 5) which should be especially efficient. All processes which use conventional lithography are limited due to misalignment errors which adversely affect the position of the dielectric via on top of the mesa. Dry-etch methods are the most commonly employed methods for forming the dielectric via on top of the mesa even though they damage the underlying p-type layers, since they offer the best repeatability and control of features sizes. Neither wet etching or liftoff methods damage the p-type layer, but have other drawbacks (discussed above and summarized in Table 1) that make them unsuitable for fabrication of small microLED mesas. Embodiments of the present invention disclosed herein achieve an undamaged p-type layer, an (e.g., perfectly) centered dielectric via, and chemically treated and ALD passivated sidewalls. Processes according to embodiments described herein are also commercially viable in the sense that they use common semiconductor manufacturing methods and do not add (and actually reduce) the typical number of steps require to form a microLED mesa.

There is growing interest in microLED devices with lateral dimensions between 1-10 μm. Reductions in external quantum efficiency (EQE) due to increased nonradiative recombination at the surface becomes an issue at small sizes. Previous attempts to study size-dependent EQE trends have been limited to dimensions above 5 μm, partly due to fabrication challenges. Here, we present the first size-dependent EQE data for InGaN microLEDs down to 1 μm in diameter by employing a novel fabrication method utilizing standard semiconductor process techniques (lithography and etching). Furthermore, differences in EQE trends for blue and green InGaN microLEDs arc compared for the first time. Green wavelength devices prove to be less susceptible to reductions in efficiency with decreasing size; consequently, green devices attain higher EQEs than blue devices below 10 μm despite lower internal quantum efficiencies (IQEs) in the bulk material. This is explained by smaller surface recombination velocities (SRVs) with increasing indium content due to enhanced carrier localization. This finding has large implications for elusive red wavelength microLEDs, suggesting that InGaN-based red microLEDs will be superior to AlGaInP-based devices due to significantly lower SRVs.

### Further Example: Comparison of Size-Dependent Characteristics of Blue and Green InGaN microLEDs Down to 1 μm in Diameter

MicroLEDs (also known as micro-LED, μLED) have the potential to replace organic light-emitting diode (OLED) and liquid-crystal display (LCD) technologies in a variety applications. Compared to LCD and OLED, microLEDs offers a number of performance benefits including increased brightness and reliability, reduced power consumption, longer lifetimes, and smaller form factors. [1]

For most display applications, microLEDs with lateral dimensions below 10 μm will be required to reduce material cost. For example, IHS Research and Veeco predict mesa sizes of 9 μm and 3 μm are necessary for 55″ 4K TVs and smartphones, respectively, in order to meet cost targets necessary for commercialization. [2] Near-eye and other microdisplays (such as those for augmented reality) will also require sizes under 5 μm, although the primary driving factors for these displays are high pixel density requirements and small form factors. [3]

Unfortunately, the external quantum efficiency (EQE) of microLEDs decreases as lateral dimensions are reduced. [4-6]. This originates from an increased surface-area-to-volume ratio which increases nonradiative Shockley-Read-Hall (SRH) recombination at the edge of the mesa. The etched surface contains crystallographic defects, impurities and dangling bonds which introduce trap states within the bandgap that act as nonradiative recombination centers.[7.8].

Size-dependent efficiency in microLEDs can be incorporated into the ABC-model by defining an effective SRH coefficient which depends on the active region perimeter,

P, area, A, surface recombination velocity (SRV), vs, and bulk SRH coefficient, A⁰. [7]

$${A}^{′} = {A}_{0} + {v}_{s} \frac{𝒫}{𝒜} \qquad ( 1 )$$

The internal quantum efficiency (IQE) becomes [4,5,7,8]:

$$IQE = \frac{{η}_{inj} {Bn}^{2}}{{A}^{′} n + {Bn}^{2} + {Cn}^{3}} . \qquad ( 2 )$$

In Eq. (2) n is the carrier concentration, ηᵢₙⱼ is the injection efficiency, and B and C are coefficients related to radiative and Auger recombination, respectively. Finally, the EQE is defined as the product of the IQE and light extraction efficiency, LEE.

$$EQE = IQE \times LEE = \frac{{P}_{opt} \times 〈 λ 〉}{J \times 𝒜 \times c \times h} \qquad ( 3 )$$

The right side of Eq. (3) allows for calculation of the EQE in terms of experimental parameters including the optical power, Pₒₚₜ, mean wavelength of the electroluminescence

Spectrum, <λ>, and the current density, J. Insertion of Eq. (1) and Eq. (2) into Eq. (3) reveals how the EQE is reduced as lateral dimensions decrease in agreement with experimentally observed trends. [4-6].

$${J}_{peak} ∝ {n}_{peak} = \sqrt{\frac{{A}^{′}}{C}} \qquad ( 4 )$$

Eq. (4) shows that the current density at which the IQE peaks. Jpeak, increases as mesa diameter shrinks, also in agreement with experimentally observed trends. [4-6] Authors have shown that size-dependent efficiency losses in microLEDs can be recovered through various sidewall treatments and passivation methods which reduce the SRV. [9-11].

There are no previous reports of microLED EQE trends at mesa dimensions below 5 μm, despite commercial demand [2]. This counterintuitive result is partly due to fabrication difficulties which arise at these size ranges; for instance, layer-to-layer alignment for a 1 μm microLED becomes intractable using lithography systems available to a typical academic researcher. Furthermore, sidewall recombination studies are often convoluted with processing effects which makes interpreting any observed trends challenging; for example, Olivier [12] showed that dry etching the dielectric aperture on top of microLED mesas introduced size-dependent damage to the p-contact which caused deviations from the EQE trends expected solely from sidewall recombination.

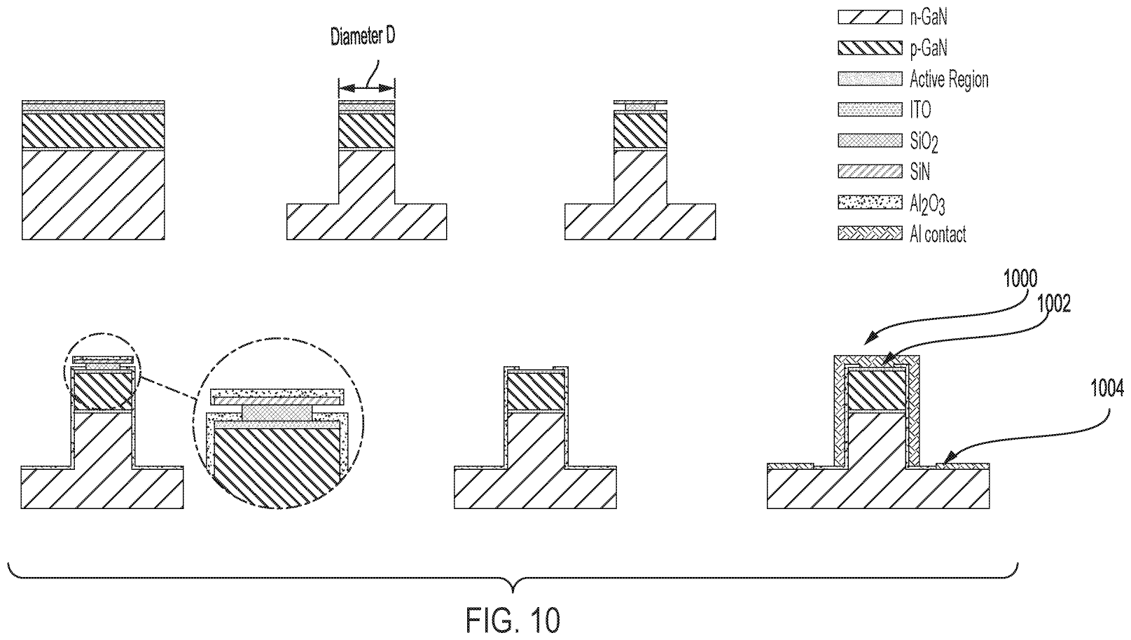

FIG. 10 illustrates the novel processing scheme used for this comparative study. As described herein, the process improves alignment and removes the need to dry etch the dielectric aperture. The core concept of the process is to form a self-aligned undercut structure on top of the mesa (FIG. 10(c)) in order to facilitate lift-off of dielectric material deposited on top of the mesa to form the dielectric aperture.

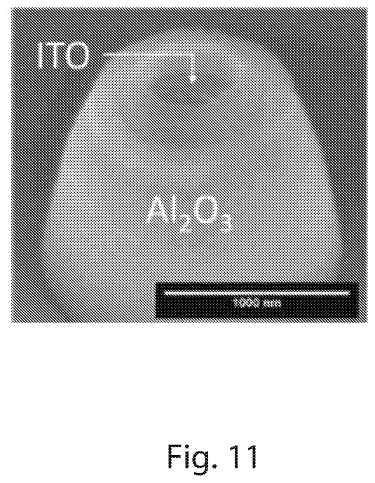

FIG. 11 shows a scanning electron microscope (SEM) micrograph image of a 1 μm microLED mesa directly after the liftoff step corresponding to FIG. 10(e).

Blue and green microLEDs (with operating wavelengths of approximately 467 nm and 532 nm, respectively) were fabricated from commercial c-plane epitaxial material grown on sapphire with diameters ranging from 1-30 micrometers using the aforementioned process. Blue and green devices were processed in parallel to limit any processing variations. For each device size, several devices were tested and their results averaged, while the error bars indicate the minimum and maximum values measured. The electro-optical characteristics of the devices are discussed below.

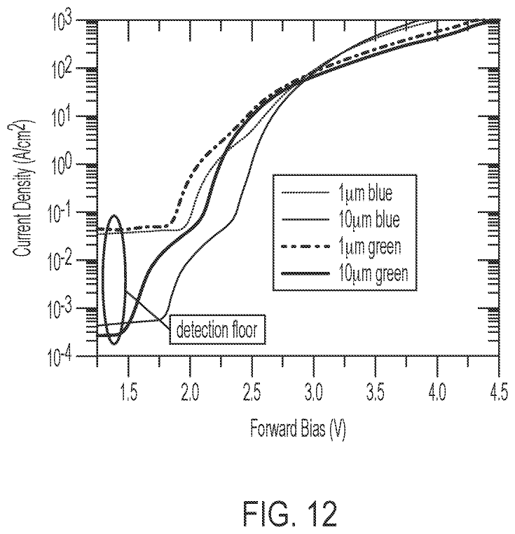

FIG. 12 compares continuous operation current-voltage characteristics for blue and green devices for 1 μm and 10 μm device sizes. When comparing device sizes (for both blue and green) at below-threshold voltages, the 1 μm devices exhibit higher current densities as a result of increased surface leakage current. [8] At higher current densities where high injection effects and series resistance dominate, the 1 μm and 10 μm curves approach similar values, indicating comparable carrier transport across device sizes. This suggests any trends observed in the EQE across device sizes are due to sidewall recombination effects and not related to other processing-related effects such as contact resistance. [8]

Optical measurements were conducted on-chip (with-out flip-chip bonding or substrate removal). Emission was collected through the sapphire substrate within approximately a 60° half-angle normal to the substrate.

The collection surface was an optical diffuser (Ocean Optics CC-3-DA) coupled to a fiber optic cable. The output of the fiber was collimated and passed through an optional neutral density (ND) filter and focused into a monochromator with a blazed grating (Horiba Jovin Yvon iHR320, 600 gr/mm) with thermoelectrically cooled CCD detector (Synapse, −70° C.) to record the electroluminescence (EL) spectra. A fiber-coupled blackbody source (Ocean Optics LS-1-CAL) was used for radiometric calibrations. The purpose of the diffuse collection surface was to make the measured power independent of the incident angle of photon flux, which may vary greatly with device diameter.[13,14] For each device, electroluminescence (EL) spectra were measured at various current densities and integrated across all relevant wavelengths to calculate Popt and EQE using the right side of Eq. (3).

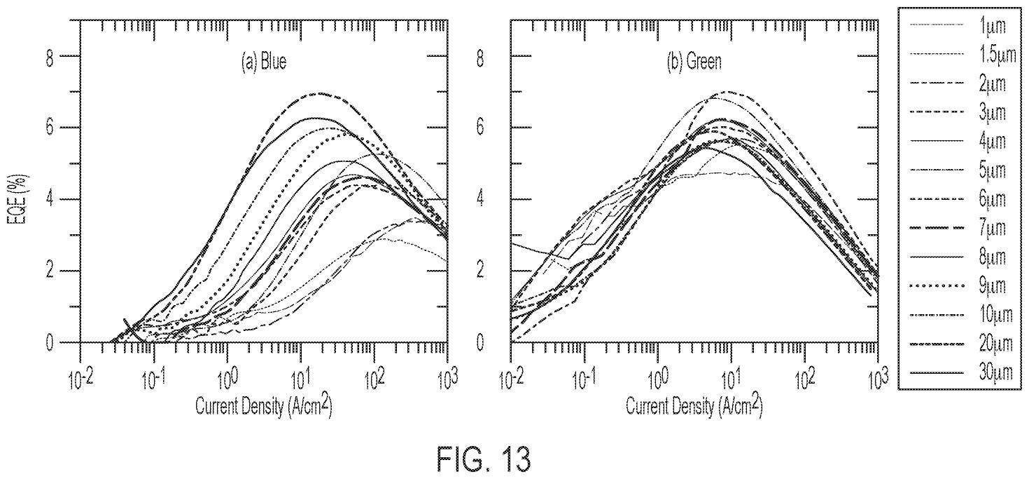

FIG. 13 shows measured EQE curves as a function of current density for devices ranging from 1-30 μm in diameter for (a) blue and (b) green wavelengths. These are the first reported results of these kind for devices less than 5 μm. The blue wavelength devices show a decrease in efficiency as size is reduced down to 1 μm as well as a shift in Jpeak to higher current densities, in agreement with reported experimental results. [4-6]. The green devices, however, do not follow the same trend, the reason for which is discussed below.

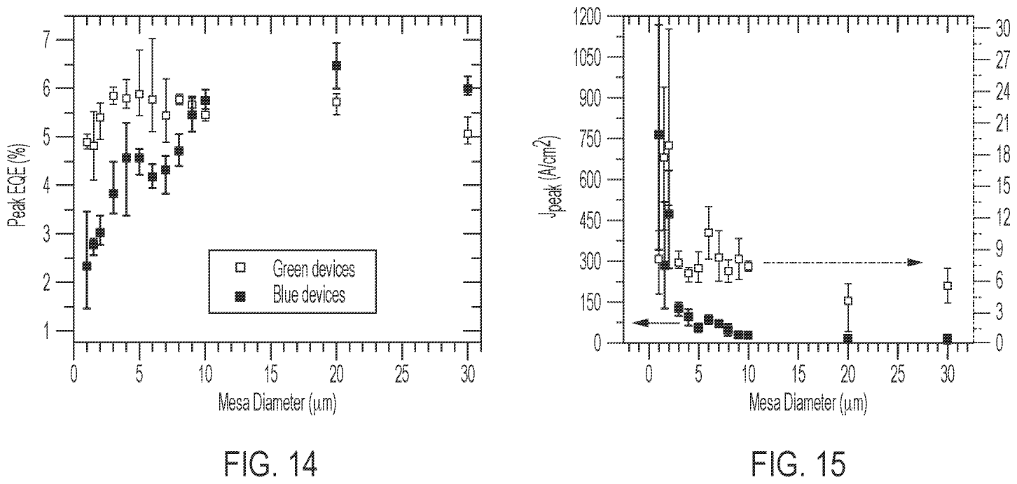

FIG. 14 plots the peak EQE versus diameter for both blue and green devices, where the upper ranges correspond the peaks of the EQE curves in FIG. 4. The EQE remains approximately constant for the larger 10 μm, 20 μm, and 30 μm device sizes for both colors. The EQE clearly begins to reduce at sizes below 10 μm and 3 μm for blue and green, respectively. It is clear that the expected reduction in EQE, as diameter is decreased, is less severe for green devices compared to blue.

In fact, green devices exhibit higher EQEs than the blue devices at diameters below 10 μm. This crossover is remarkable since it is well known that the internal quantum efficiency (IQE) of bulk green InGaN material is lower than blue material due to increased InGaN/GaN lattice mismatch which increases strain in the epitaxially grown layers. Increased strain reduces crystal quality and enhances the quantum-confined Stark effect (QCSE) which both contribute to lower IQEs observed in green InGaN LEDs. [15]

The reduced size-dependence of green devices is explained by a smaller SRV, Vs, which has been experimentally observed by other groups. [7,16,17] This effect has been attributed to enhanced carrier localization with increasing indium content due to indium clustering in the active region. [18,19] Eq. (1) reveals smaller Vₛ reduces the P/A term contribution, resulting in a smaller effective SRH coefficient, A′ This results in a specific diameter where the device set with higher IQE and EQE will crossover from blue to green. In the case of FIG. 14, the crossover occurs at 10 μm; however, the exact crossover diameter will change depending on the device geometry and relative material quality between blue and green.

Further evidence of reduced surface recombination in green devices is the shift of Jpeak to significantly lower current densities (note the difference in y-axis scales) in FIG. 15. This caused by a lower A′ in Eq. (4) due to a smaller SRV.

The finding of an EQE crossover in blue and green InGaN microLEDs may have greater implications for red microLEDs, as an analogous (but more extreme) relationship exists between red AlGaInP and red InGaN microLEDs, respectively. Large-area red AlGaInP emitters are typically much more efficient than red InGaN emitters which suffer from the same issues as green InGaN devices (poor material quality and increased QCSE due to strain), but to a greater extent. However, the SRV in red AlGaInP is even higher than blue InGaN, while the SRV of red InGaN is lower than that of green InGaN due to increased indium content and carrier localization. [7,20] Thus, it is likely a similar crossover in EQE like that shown in FIG. 14 also exists between red AlGaInP and red InGaN microLEDs, where InGaN devices would win out at smaller sizes.

In conclusion, we have presented electrically-injected device results for the smallest reported InGaN microLEDs to date (down to 1 μm) fabricated using conventional, top-down semiconductor processing methods. We also analyzed differences in the size-dependent EQE trends between blue and green wavelength InGaN microLEDs. We have found the EQE in green wavelength devices exhibits a smaller size-dependence which is attributed to a reduced SRV due to carrier localization. This results in green devices showing higher EQE values than their blue counterparts for diameters under 10 μm despite having lower bulk efficiencies.

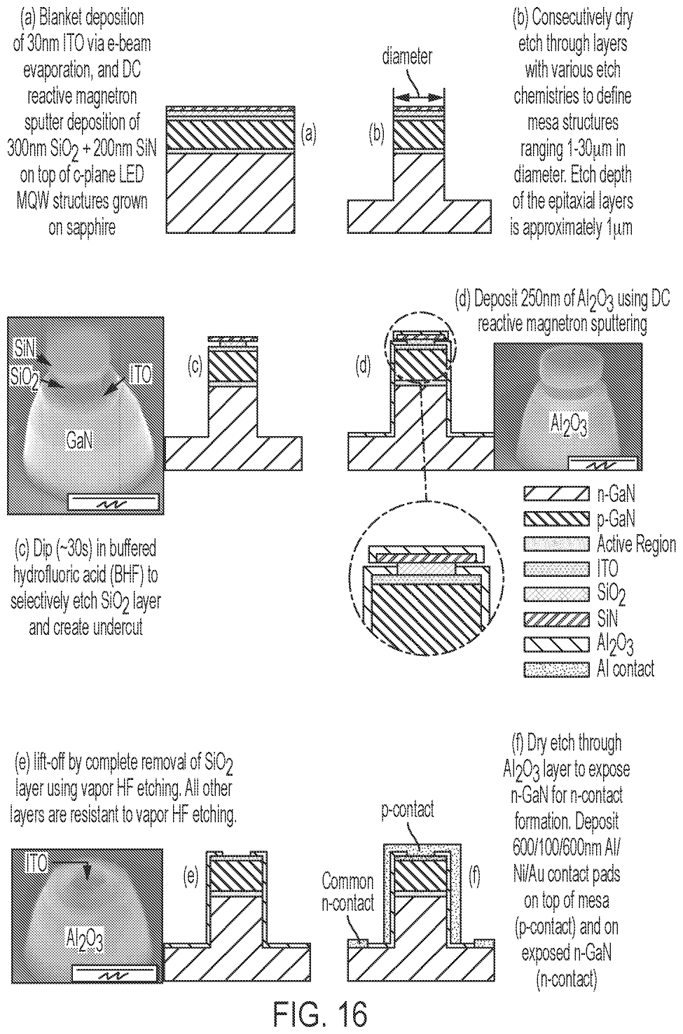

FIG. 16 shows additional details and SEM micrographs of the process developed to fabricate microLEDs down to 1 μm.

### Advantages and Improvements

There is growing interest in microLED devices or mesas with lateral dimensions between 1-10 micrometers. It is expected that such very small microLED will be required to reduce material costs enough to commercialize microLED technology for displays. The smallest mesas (˜1 micron) will also enable new markets such as augmented reality (AR) and microdisplays. However, fabricating microLEDs this size is challenging. Reductions in external quantum efficiency (EQE) due to increased nonradiative recombination at the surface becomes an issue at small sizes. Previous attempts to study size-dependent EQE trends have been limited to dimensions above 5 microns, partly due to fabrication challenges.

Embodiments of the present invention, on the other hand, allow for the fabrication of microLEDs in the very small size range. More specifically, we present the first size-dependent EQE data for InGaN microLEDs down to 1 micron in diameter by employing a novel fabrication method utilizing semiconductor processing techniques (lithography and etching).

Furthermore, the microLEDs fabricated using process embodiments described herein are more reliable and efficient than other processes since they can incorporate the features 2-4 described in “Summary of Invention” above. In addition, these features can be achieved in a relatively efficient manner utilizing semiconductor processing techniques, which make the process friendly for commercialization due to low costs.

A microLED mesa structure and the process leading to its formation (according to one or more embodiments disclosed herein) have a large number of commercial advantages.

A summary of commercial advantages of one or more embodiments of the present invention includes:

1. A centered/aligned (e.g., in one or more examples, perfectly centered/aligned) dielectric via, which improves microLED device performance/efficiency.

2. Significantly or substantially undamaged or undamaged p-contact due to ion bombardment, which improves microLED device performance/efficiency.

3. Reduced nonradiative recombination from sidewall treatments, which improves microLED device performance/efficiency.

4. Capability of fabricating mesas down to 1 micron in size (or slightly smaller), which enables new markets (AR) and reduces material costs.

5. Use of traditional top-down semiconductor fabrication methods, which reduces cost, with no or reduced need to build new infrastructure for processing.

6. A reduced number of lithography steps compared to standard methods, which reduces cost and reduces the number of processing steps required.

7. A robust process which can altered/modified/changed to specific applications while maintaining the general process and structure.

Furthermore, differences in EQE trends for blue and green InGaN microLEDs are compared for the first time. Green wavelength devices prove to be less susceptible to reductions in efficiency with decreasing size: consequently, green devices attain higher EQEs than blue devices below lateral dimensions of 10 microns despite lower internal quantum efficiencies (IQEs) in the bulk material. This is explained by smaller surface recombination velocities (SRVs) with increasing indium content due to enhanced carrier localization. This finding has large implications for elusive red wavelength microLEDs, suggesting that InGaN-based red microLEDs will be superior to AlGaInP-based devices due to significantly lower SRVs.

### Device and Method Examples

Example devices and methods include, but are not limited to, the following (referring also to FIGS. 3, 5, 6A-7C, and 8-16).

1. A method of making a light emitting device 1000, comprising:

(a) obtaining an epitaxial structure 302 for the device, the epitaxial structure including an n-type layer 304, a p-type layer 306, and an active region 308 between the n-type layer and the p-type laver;

(b) depositing a first hardmask layer 310 comprising a first material (e.g., silicon dioxide (SiO2) on the epitaxial structure. The first hardmask layer is resistant (e.g., at least partially resistant) to a wet chemical solution used in step (e);

(c) depositing a second hardmask layer 312 comprising a second material (e.g., silicon nitride, SiN) on the first hardmask layer. The second hardmask layer is resistant to the wet chemical solution used in step (e);

(d) patterning the hardmask layers 310, 312 and the epitaxial structure using lithography so as to form a mesa 314 comprising the epitaxial structure, wherein the patterning includes selectively etching the first hardmask layer over the second hardmask layer so as to form an undercut structure comprising the second hardmask layer extending laterally beyond the edges of the underlying first hardmask layer;

(e) performing one or more sidewall treatments, e.g., so as to remove impurities, defects and/or passivate dangling bonds from sidewalls of the mesa. In one or more examples, the sidewall treatments include a dip of the sidewalls in a wet chemical solution and/or passivation;

(f) deposition of a an ALD layer 316 (e.g., passivation layer) on the sidewalls 360 using atomic layer deposition (ALD). In one or more examples, the one or more sidewall treatments of step (c) include the deposition of the ALD layer;

(g) depositing a dielectric layer 318 on the ALD layer using a directional deposition method so that discontinuity 319 in the dielectric layer is formed, the discontinuity exposing the ALD layer surrounding the first hardmask layer;

(h) removing the ALD layer surrounding the first hardmask layer and exposed by the discontinuity, using an etching technique; and

(i) removing the first hardmask layer using etching. In one example, removing the first hardmask layer removes all of the layers above the first hardmask layer and forms a via hole 320 in the material of the hardmasks on top of the mesa, wherein the via exposes a top surface of the epitaxial structure in the mesa. In one or more examples, the step comprises etching the first hardmask layer, thereby removing the first hardmask layer and all of the layers above the first hardmask layer, leaving a via hole 320 in the dielectric layer on top of the mesa having a location 330 and a first area 332 defined by the position 334 and second surface 336 area of patterned hardmask layer prior to removal of patterned first hardmask layer, so that the via hole exposes a top surface 338 of the epitaxial structure in the mesa

2. The method of example 1, wherein the first material and the second material comprise one or more dielectrics, e.g., so that the via hole is in a dielectric layer on top of the mesa.

3. The method of examples 1 or 2, wherein the device is a micro light emitting diode 1000.

4. The method of example 3, wherein the micro led includes a mesa having a top surface 322 having surface area 324 of 10 microns by 10 microns or less.

5. The method of any of the preceding examples, wherein etching removing the hardmasks and the ALD material comprises vapor or wet etching.

6. The method of any of the preceding examples, wherein the ALD layer comprises a dielectric and the dielectric layer on the ALD layer is thicker than the ALD layer.

7. The method of any of the preceding examples, wherein the dielectric layer deposited on the ALD layer is resistant to the etchant used to remove the hardmask layers.

8. The method of any of the preceding examples, wherein removing all of the layers above the first hardmask layer includes removing the second hardmask layer and a photoresist layer used to pattern the mesa using the photolithography.

9. The method of any of the examples 1-8, further comprising depositing metallization or metal 1002 in the via hole so as to form an ohmic contact to the top surface 322 of the epitaxial structure comprising an n-type layer or a p-type layer.

10. The method of any of the preceding examples 1-9, wherein the epitaxial structure comprises III-nitride.

11. A micro light emitting diode 1000, comprising: a mesa 314 comprising an epitaxial structure 302 and having a top surface 322 with an area 324 less than 10 micrometers by 10 micrometers ore less and/or at least one of a diameter D, a largest width W, or a largest dimension W of 10 micrometers or less;

a dielectric 318 on the top surface 322; and

a hole or via hole 320 in the dielectric that is centered or self aligned on the top surface 322.

12. The micro light emitting diode of example 11, wherein the area 324 is less than 1 micron by 1 micron, less than 0.5 microns by 0.5 microns, and/or at least one of the diameter D, the largest width W, or the largest dimension W is 5 micrometers or less, 1 micrometer or less, or 0.5 micrometers or less.

13. The LED of example 12, further comprising metallization or metal 1002 in the hole or via hole, the metallization or metal forming an ohmic contact with the epitaxial structure.

14. The micro LED of any of the examples 11-13, wherein the epitaxial structure comprises an n-type layer 304, a p-type layer 306, and an active region 308 between the n-type layer and the p-type layer, wherein the metallization or metal 1002 forms an ohmic contact with the n-type layer or the p-type layer exposed by the via hole 320 and the active region emits electromagnetic radiation 804 when an electric field is applied across the n-type layer and the p-type layer using the metallization.

15. The micro LED of any of the examples 11-14, wherein the epitaxial structure comprises an n-type layer 304, a p-type layer 306, and an active region 308 between the n-type layer and the p-type layer, a first contact 1002 in the hole 320 (or via hole) forms an ohmic contact with the n-type layer or the p-type layer, and the active region 308 emits electromagnetic radiation 804 in response an electric field across the n-type layer and the p-type layer, the electric field formed by a potential difference between the first contact 1002 (e.g., p-contact) and a second contact (1004, e.g., n-contact) to the micro light emitting diode.

16. The device or microLED of any of the examples 11-15, wherein at least one of the first contact and the second contact comprise a metal layer (e.g., aluminum, Al).

17. The device or microLED of any of the examples 11-16, wherein the first contact or the second contact are connected to the p-type layer 306 via an n-type region in a tunnel junction.

18. The microLED of any of the examples 11-17, wherein the via hole 320 or hole has a diameter D of 2 microns or less.

19. The microLED of any of the examples 11-18, wherein the hole (e.g., via hole) has a first center C1 centered to within 0.5% of a second center C2 of the top surface 338.

20. The micro light emitting diode of any of the examples 11-19, wherein the light emitting diode is plasma damage free.

21. An array 800 of the micro light emitting diodes 1000 of examples 11-20.

22. A display comprising the array of example 21.

23. An array of micro light emitting diodes manufactured using the method of examples 1-10.

24. The method or device or microLED of any of the examples 1-23, wherein each of the micro light emitting diodes emit electromagnetic radiation for a current density of at least 100 amps per centimeter square at a bias of at least 2.5 volts.

25. A device comprising the micro light emitting diode of any of the examples 11-24 manufactured using the method of examples 1-10.

26. The device or microLED or method of any of the examples 1-23, wherein the epitaxial structure comprises or consists essentially of a semiconductor including, but not limited to, III-nitride or III-V materials.

27. The device or microLED of any of the examples 1-16, wherein the microLED comprises III-nitride.

28. The device or microLED of any of the examples 11-27, wherein the mesa includes sidewalls and at least one of a dielectric or passivation on the sidewalls.

29. The microLED of any of the examples, wherein the via hole is centered to within 0.5% of the center of the top surface.

30. The microLED of any of the examples, wherein the microLED or mesa has a diameter D or largest width W in a range of 500 nanometers (nm)-100 micrometers (500 nm≤W≤100 micrometers).

Nomenclature

GaN and its ternary and quaternary compounds incorporating aluminum and indium (AlGaN, InGaN, AlInGaN) are commonly referred to using the terms (Al,Ga,In)N, III-nitride, III-N, Group III-nitride, nitride, Group III-N, Al_{(1-x-y)}In_{y}GaₓN where 0<x<1 and 0<y<1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga. Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials. Boron (B) may also be included.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero 1 Miller index.

Some commonly observed examples of semi-polar planes include the (11-22), (10-11), and (10-13) planes. Other examples of semi-polar planes in the wurtzite crystal structure include, but are not limited to, (10-12), (20-21), and (10-14). The nitride crystal's polarization vector lies neither within such planes or normal to such planes, but rather lies at some angle inclined relative to the plane's surface normal. For example, the (10-11) and (10-13) planes are at 62.98° and 32.06° to the c-plane, respectively.

### REFERENCES

The following references are incorporated by reference herein
[1] K. Ding, V. Avrutin, N. Izyumskaya, Ü. Özgür, and H. Morkoç, “MicroLEDs, a Manufacturability Perspective,” Applied Sciences 9 (2019).
[2] A. Paranjpe, J. Montgomery, S. M. Lee, and C. Morath, “45-2: Invited Paper: Micro-LED Displays: Key Manufacturing Challenges and Solutions,” SID Symposium Digest of Technical Papers 49, 597-600 (2018).
[3]E. H. Virey and N. Baron, “45-1: Status and Prospects of microLED Displays,” SID Symposium Digest of Technical Papers 49, 593-596 (2018).
[4] F. Olivier, A. Daami, C. Licitra, and F. Templier. “Shockley-Read-Hall and Auger non-radiative recombination in GaN based LEDs: A size effect study,” Applied Physics Letters 111 (2017).
[5] P. Tian, J. J. McKendry, Z. Gong, B. Guilhabert, I. M. Watson. E. Gu, Z. Chen. G. Zhang, and M. D. Dawson, “Size-dependent efficiency and efficiency droop of blue InGaN micro-light emitting diodes,” Applied Physics Letters 101 (2012).
[6] D. Hwang, A. Mughal, C. D. Pynn, S. Nakamura, and S. P. DenBaars, “Sustained high external quantum efficiency in ultra-small blue III-nitride micro-LEDs,” Applied Physics Express 10, 032101 (2017).
[7] K. A. Bulashevich and S. Y. Karpov, “Impact of surface recombination on efficiency of III-nitride light-emitting diodes,” Physica Status Solidi—Rapid Research Letters 10, 480-484 (2016).
[8] E. F. Schubert, Light-Emitting Diodes (Cambridge University Press, Cambridge, 2006).
[9] M. S. Wong, C. Lee, D. J. Myers. D. Hwang, J. A. Kearns, T. Li, J. S. Speck, S. Nakamura, and S. P. DenBaars, “Size-independent peak efficiency of III-nitride micro-light-emitting-diodes using chemical treatment and sidewall passivation,” Applied Physics Express 12, 097004 (2019).
[10] M. S. Wong, D. Hwang, A. I. Alhassan, C. Lee, R. Ley, S. Nakamura. and S. P. DenBaars, “High efficiency of II-nitride micro-light-emitting diodes by sidewall passivation using atomic layer deposition,” Opt. Express 26, 21324-21331 (2018).
[11]W. H. Choi, G. You, M. Abraham, S.-Y. Yu, J. Liu, L. Wang, J. Xu, and S. E. Mohney, “Sidewall passivation for InGaN/GaN nanopillar light emitting diodes,” Journal of Applied Physics 116, 013103 (2014).
[12] F. Olivier, S. Tirano, L. Dupré, B. Aventurier, C. Largeron, and F. Templier, “Influence of size-reduction on the performances of GaN-based micro-LEDs for display application,” Journal of Luminescence 191, 112-116 (2017).
[13] K. A. Bulashevich, S. S. Konoplev, and S. Y. Karpov, “Effect of Die Shape and Size on Performance of III-Nitride Micro-LEDs: A Modeling Study,” Photonics 5 (2018), 10.3390/photonics5040041.
[14] H. W. Choi, C. W. Jeon, M. D. Dawson, P. R. Edwards, R. W. Martin, and S. Tripathy. “Mechanism of enhanced light output efficiency in InGaN-based microlight emitting diodes,” Journal of Applied Physics 93, 5978-5982 (2003).
[15] Q. Zhou, X. M, and W. H, “Internal quantum efficiency improvement of InGaN/GaN multiple quantum well green light-emitting diodes,” Opto-Electronics Review 24, 1-9 (2016).
[16] H. Kitagawa, M. Fujita. T. Suto, T. Asano, and S. Noda, “Green GaInN photonic-crystal light-emitting diodes with small surface recombination effect,” Applied Physics Letters 98, 181104 (2011). 17H. Kitagawa, T. Suto. M. Fujita, Y. Tanaka, T. Asano, and S. Noda, “Green Photoluminescence from GaInN Photonic Crystals.” Applied Physics Express 1, 032004 (2008).
[18] S. F. Chichibu, A. Uedono, T. Onuma, B. a Haskell, A. Chakraborty, T. Koyama. P. T. Fini, S. Keller, S. P. Den-baars, J. S. Speck, U. K. Mishra, S. Nakamura, S. Yamaguchi, S. Kamiyama, H. Amano, I. Akasaki, J. Han, and T. Sota, “Origin of defect-insensitive emission probability in In-containing (Al,In,Ga)N alloy semiconductors.” Nature materials 5, 810-816 (2006).
[19] Y. Narukawa, Y. Kawakami, M. Funato, S. Fujita, S. Fujita, and S. Nakamura. “Role of self-formed InGaN quantum dots for exciton localization in the purple laser diode emitting at 420 nm,” Applied Physics Letters 70, 981-983 (1997).
[20] J.-T. Oh, S.-Y. Lee, Y.-T. Moon, J. H. Moon. S. Park, K. Y. Hong. K. Y. Song, C. Oh, J.-I. Shim, H.-H. Jeong, J.-O. Song, H. Amano, and T.-Y. Seong, “Light output performance of red AlGaInP-based light emitting diodes with different chip geometries and structures,” Opt. Express 26, 11194-11200 (2018).
[21] “Comparison of size dependent characteristics of blue and green InGaN microLEDs down to 1 μm in diameter” Appl. Phys. Lett. 116, 071102 (2020): https://doi.org/10.1063/1.5144819 by Jordan Smith and Steven DenBaars et. al.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1.-10. (canceled)

11. A micro light emitting diode (microLED), comprising:
a mesa comprising an epitaxial structure and having at least one of:
a top surface with an area of 10 micrometers squared or less, or
at least one of a diameter, a largest width, or a largest dimension of 10 micrometers or less;
a dielectric on the top surface; and
a hole in the dielectric that is centered or self aligned on the top surface.

12. The micro light emitting diode of claim 11, comprising the area being:
1 micron squared or less, or
0.5 microns squared or less.

13. The micro light emitting diode of claim 11, comprising at least one of the diameter, the largest width, or the largest dimension being:
5 microns or less,
1 micron or less, or
0.5 microns or less.

14. The micro LED of claim 11, wherein the micro LED comprises III-nitride.

15. The microLED of claim 14, further comprising metallization in the hole forming an ohmic contact with the epitaxial structure.

16. The micro LED of claim 11, wherein:
the epitaxial structure comprises an n-type layer, a p-type layer, and an active region between the n-type layer and the p-type layer,
a first contact in the hole forms an ohmic contact with the n-type layer or the p-type layer, and
the active region emits electromagnetic radiation in response an electric field across the n-type layer and the p-type layer, the electric field formed by a potential difference between the first contact and a second contact to the micro light emitting diode.

17. The microLED of claim 11, wherein the hole has a diameter of 2 microns or less.

18. The microLED of claim 11, wherein the hole has a first center within 0.5% of a second center of the top surface.

19. The micro light emitting diode of claim 11, wherein the light emitting diode is plasma damage free.

20. An array of the micro light emitting diodes of claim 11.

21. A display comprising the array of claim 20, wherein the array comprises pixels each comprising at least one of the micro light emitting diodes.

22. (canceled)

23. The microLED of claim 11, wherein:
each of the micro light emitting diodes emit electromagnetic radiation for a current density of at least 100 amps per centimeter square in the epitaxial structure comprising in response to a bias of at least 2.5 volts applied across the epitaxial structure between a first contact to the epitaxial structure in the hole and a second contact to the epitaxial structure, and
the first contact is electrically connected to an n-type layer in the epitaxial structure and the second contact is electrically connected to a p-type layer in the epitaxial layer, or the first contact is electrically connected to the p-type layer and the second contact is electrically connected to a n-type layer.

24. The microLED of claim 23, wherein the first contact or the second contact are connected to the p-type layer via an n-type region in a tunnel junction.

25. The microLED of claim 23, wherein at least one of the first contact and the second contact comprise a metal layer.

26. (canceled)

27. The microLED of claim 11, wherein the epitaxial structure comprises or consists essentially of a semiconductor including comprising a III-nitride material or a III-V material.

28. The microLED of claim 11, wherein the mesa includes sidewalls and at least one of a dielectric or passivation on the sidewalls.

29. A micro light emitting diode, comprising:
a mesa comprising an epitaxial structure and having at least one of:
a top surface with an area of 10 micrometers squared or less, or
at least one of a diameter, a largest width, or a largest dimension of 10 micrometers or less;
a dielectric on the top surface; and
a hole in the dielectric that is centered or self aligned on the top surface, fabricated using a process comprising:
(a) obtaining the epitaxial structure including an n-type layer, a p-type layer, and an active region between the n-type layer and the p-type layer;
(b) depositing a first hardmask layer comprising a first material on the epitaxial structure;
(c) depositing a second hardmask layer comprising a second material on the first hardmask layer, wherein the first hardmask layer and the second hardmask layer are at least partially resistant to a wet chemical solution used in step (e);
(d) patterning the first hardmask layer, the second hardmask layer, and the epitaxial structure using lithography so as to form the mesa comprising the epitaxial structure, wherein the patterning includes selectively etching the first hardmask layer over the second hardmask layer so as to form an undercut structure comprising the second hardmask layer extending laterally beyond the edges of the underlying patterned first hardmask layer;
(e) performing one or more sidewall treatments so as to remove impurities, defects and passivate dangling bonds from sidewalls of the mesa, wherein the sidewall treatments include a dip of the sidewalls in the wet chemical solution;
(f) depositing an ALD layer on the sidewalls using atomic layer deposition (ALD);
(g) depositing the dielectric layer on the ALD layer using a directional deposition method so that a discontinuity in the dielectric layer is formed, the discontinuity exposing the ALD layer surrounding the first hardmask layer;
(h) removing the ALD layer surrounding the first hardmask layer and exposed by the discontinuity, using an etching technique; and
etching the first hardmask layer, thereby removing the first hardmask layer and all of the layers above the first hardmask layer, leaving the hole in the dielectric layer on top of the mesa having a location and a first area defined by the position and second surface area of patterned hardmask layer prior to removal of patterned first hardmask layer, so that the hole exposes the top surface of the epitaxial structure in the mesa.
